(19) United States
(12) Patent Application Publication
(10) Pub. No.: US 2023/0324485 A1
(43) Pub. Date: Oct. 12, 2023

(54) RADIO FREQUENCY FIELD EMISSION SYSTEM FOR MAGNETIC RESONANCE IMAGING

(71) Applicants: UNIVERSITÉ D'AIX MARSEILLE, Marseille (FR); Centre National de la Recherche Scientifique, Paris (FR); Ecole Centrale de Marseille, Marseille (FR); Multiwave Imaging, Marseille (FR)

(72) Inventors: Marc Dubois, Marseille (FR); Kaizad Rustomji, Marseille (FR); Tania Del Socorro Vergara Gomez, Marseille (FR); Elodie Virginie Emilia Georget, Septemes Les Vallons (FR); Frank Kober, Marseille (FR); Redha Abdeddaim, Marseille (FR); Stanislas Pierre Alain Rapacchi, Marseille (FR); Stefan Enoch, Marseille (FR); Tryfon Antonakakis, Genève (FR)

(73) Assignees: UNIVERSITÉ D'AIX MARSEILLE, Marseille (FR); Centre National de la Recherche Scientifique, Paris (FR); Ecole Centrale de Marseille, Marseille (FR); Multiwave Imaging, Marseille (FR)

(21) Appl. No.: 18/011,406

(22) PCT Filed: Jun. 15, 2021
(86) PCT No.: PCT/EP2021/066142

§ 371 Date: May 3, 2023

(30) Foreign Application Priority Data
Jun. 23, 2020 (FR) 2006574

(51) Int. Cl. G01R 33/389; G01R 33/34; G01R 33/48

(52) U.S. Cl. CPC G01R 33/389; G01R 33/34076; G01R 33/4806

(57) ABSTRACT

A system is described for emitting a radiofrequency field for a magnetic resonance imaging device, including a volumetric antenna that emits a radiofrequency field, a device for homogenizing the radiofrequency field arranged between said volume antenna and a part of the body to be imaged. The device may include a first continuous metal track with an overall length of approximately 0.5 to approximately 1.5 times said wavelength of the radio frequency field. The first metallic track may occupy a surface with a largest dimension ranging between approximately 5% and approximately 15% of said wavelength of the radio frequency field. The first metal track is arranged in a pattern including a plane of symmetry that is normal to the electrical component of the radio frequency field, so as to give the device an electric dipole property including a natural frequency strictly greater than the frequency of the radio frequency field.

### TECHNICAL FIELD OF THE INVENTION

The present description relates to a system for emitting a radio frequency field for magnetic resonance imaging. The present description also relates to a method for emitting a radio frequency field.

### PRIOR ART

Magnetic resonance imaging (MRI) devices generate a main static magnetic field by means of intense magnets and an excitation radio frequency (RF) field by means of one or more transmission antenna(s). The excitation RF field penetrates an object to be imaged (for example, a human body or a part of the human body) and interacts with atomic nuclei (for example, protons) present in the object to be imaged in order to excite them. In order for this interaction to be optimal, the excitation RF field must be resonant with the atomic nuclei. To this end, the excitation RF field is emitted at a particular frequency, called Larmor frequency, of the atomic nucleus that is used.

The Larmor frequency is an increasing function of the main magnetic field. Thus, for a proton (i.e., a hydrogen nucleus), it is approximately 64 MHz in a main magnetic field of 1.5 T, while for a field of 7 T it is approximately 300 MHz. By returning to their state of equilibrium, the atomic nuclei emit an RF signal that is measured by the MRI device and provides the data required for reconstructing an image of the object, called the MRI image. In particular, among MRI devices there is a distinction between “low-field” and “high-field” devices, the main magnetic field of which is approximately between 1.5 T and 3 T, and “ultra-high-field” devices, the main magnetic field of which can reach approximately 7 T and more. The use of very intense magnetic fields allows a significant increase in the signal-to-noise ratio (SNR) of the measurement of the RF signal, allowing the MRI images to be provided but it is accompanied by an increase in the Larmor frequency, and therefore a reduction in the wavelength required for the excitation RF field.

Clinical low-field and high-field devices are equipped with an antenna, called body-antenna, for emitting the excitation RF field to the atomic nuclei intended to be fairly homogeneously studied throughout the body.

The use of a body-antenna is no longer possible in the case of ultra-high-field MRI devices that require excitation RF fields for which the wavelength is too low (11 cm in the human body at 300 MHz) to be able to be homogeneously transmitted throughout the body by a single antenna.

The strategy then generally involves using antennas dedicated to certain parts of the body (that will be called volumetric antennas in the present description). For example, for the head, birdcage type volumetric antennas can be used.

The volumetric antennas that are used then emit the excitation RF field required for measuring in areas of limited size. Despite the limitation of the area to be imaged, the problems of the inhomogeneity of the excitation RF field still partly remain. Moreover, the problems of the inhomogeneity of the excitation RF field also occur in the case of a high-field MRI applied to the torso (for example, the thorax, the abdomen or the pelvis).

Examples of devices aimed at improving the homogeneity of the excitation RF field include dielectric pads inserted between the volumetric antenna and the part of the body to be imaged in order to more homogeneously redistribute the excitation RF field in the part of the body to be imaged.

As disclosed in Teeuwisse, W. M. et al., (“Quantitative assessment of the effects of high-permittivity pads in 7 Tesla MRI of the brain.” Magnetic resonance in medicine 67.5 (2012) pg. 1285-1293), such dielectric pads can be produced based on a solvent (for example, water) and particles of material with a higher dielectric constant in order to make them thinner and to improve comfort when they are used.

However, such a device has a short lifetime due to the evaporation of the water and the sedimentation of the particles. In addition, handling them as a result of their regular use accelerates the sedimentation, which quickly degrades the performance capabilities of the pad.

Published patent application EP 3550321 describes another example of a dielectric pad containing a polar solvent, a dispersing agent and a dielectric compound for reducing the problem of the sedimentation of the particles and for improving the distribution of the particles in the pad. However, the spatial requirement of these dielectric pads is such that it makes them difficult to use when a minimum amount of space is available between the part of the body to be imaged and the volumetric antenna. Moreover, the pad poses a risk of perforating and thus spreading the liquids that it contains on the body, which can result in a danger to health. Furthermore, Motovilova et al., (“Hilbert curve-based metasurface to enhance sensitivity of radio frequency coils for 7-T MRI”, IEEE Transactions on Microwave Theory and Techniques, 2018, Vol. 67, No. 2, pg. 615-625), proposes improving the homogeneity of an RF field emitted by a surface antenna (of the microstrip type) by placing a metasurface close to the surface antenna with negative magnetic permeability allowing the RF field to be concentrated like a magnetic lens. In Motovilova et al., the metasurface includes a metal track that forms a magnetic dipole excited by the magnetic component of the electromagnetic field emitted by the microstrip antenna.

However, in this configuration, the metasurface interacts with a surface antenna and is not optimal for use in a volumetric antenna, in particular a birdcage type volumetric antenna. The present description describes a system comprising alternative devices for homogenizing the excitation RF field for an MRI device, allowing the problems of the prior art to be addressed.

### SUMMARY OF THE INVENTION

In the present description, the term “comprise” means the same as “include” or “contain”, and is inclusive or open and does not exclude other elements not described or shown. Furthermore, in the present description, the term “approximately” or “substantially” is synonymous with (means the same as) a margin less than and/or greater than 10%, for example, 5%, of the respective value.

According to a first aspect, the present description relates to a system for emitting a radio frequency field for a magnetic resonance imaging device, said radio frequency field comprising a spectrum centered on a given wavelength, said system comprising:
a volumetric antenna configured to emit said radio frequency field, said volumetric antenna being configured to be placed around a part of a body to be imaged; and
a device for homogenizing the radio frequency field configured to be arranged between said volumetric antenna and said part of the body to be imaged;
wherein the homogenizing device comprises:
   at least one first continuous metal track with an overall length of approximately 0.5 to approximately 1.5 times said wavelength of the radio frequency field; wherein:
   said first metal track occupies a surface with a largest dimension ranging between approximately 5% and approximately 15% of said wavelength of the radio frequency field;
   wherein said first metal track is arranged in a pattern comprising a plane of symmetry that is normal to the electrical component of the radio frequency field emitted by the volumetric antenna, so as to provide the homogenizing device with an electric dipole property comprising a natural frequency strictly higher than the frequency corresponding to said wavelength of the radio frequency field.

In the present description, reference is also made to the frequency of the radio frequency field corresponding to the wavelength of the radio frequency field, with the frequency of the radio frequency field being connected to the wavelength of the radio frequency field by the equation

$$f = \frac{c}{λ} ,$$

where f is the frequency of the radio frequency field, λ is the wavelength of the radio frequency field and c is the speed of light in the void.

In the present description, the frequency of the radio frequency field is the Larmor frequency used in an MRI device.

According to the present description, the surface “occupied” by a metal track is the surface of an area in which the metal track is inscribed, for example, a rectangular area or a square area. The applicants have shown that the device according to the present description allows the radio frequency field emitted by a volumetric antenna of an MRI device to be redistributed and thus improves the homogeneity of the distribution of the radio frequency field in a part of the body to be imaged. Better homogeneity of the radio frequency field allows MRI images to be obtained that exhibit a better contrast.

The applicants have also shown that the device according to the present description does not disrupt the reception of the RF signal (generated by the atomic nuclei in the part of the body to be imaged) by the reception channels of an array of surface antennas of an MRI device. The applicants have also shown that the device according to the present description does not increase the radio frequency field level to levels that are dangerous for the body.

According to one or more embodiment(s), said first metal track occupies a surface with a largest dimension ranging between approximately 5 cm and approximately 15 cm. This advantageously allows said metal track to cover a part of the human body such as a head or a pelvic area and to be able to homogenize the radio frequency field throughout this area. The metal track is arranged to provide the device with an electrical dipole property that can interact with a volumetric antenna. This implies that the metal track includes a plane of symmetry that is normal to the electrical component of the RF field emitted by the antenna. This also particularly implies an orientation of the metal track whereby a straight line connecting two ends (also called two poles) of the metal track is parallel to the electrical component of the RF field.

This distinguishes the metal track according to the invention from the metasurfaces of the prior art, in particular the metasurfaces disclosed by Motovilova et al., which are configured to form a magnetic dipole excited by the magnetic component of the RF field of the antenna. Thus, the metasurfaces disclosed in Motovilova et al. cannot be effectively used as an electric dipole.

By virtue of the electric dipole having a natural frequency strictly higher than the frequency corresponding to the wavelength of the radio frequency field this allows the device to interact with the radio frequency field in order to homogenize it without being resonant with said radio frequency field.

In the present description, the natural frequency of an electric dipole is understood to be the frequency of the electromagnetic field emitted by this dipole when said dipole is freely evolving.

According to one or more embodiment(s), said first metal track is further arranged in a pattern comprising a first and a second 3^{rd} order Hilbert curve, with said first and second curves being connected to each other.

The use of Hilbert curves advantageously allows the metal track to be folded by a given overall length in order to reduce the two-dimensional space that it occupies on a surface, while retaining useful axial symmetry properties so that the metal track forms an electric dipole configured to interact with the radio frequency field. The fact of using several Hilbert curves connected to each other in order to form a continuous metal track thus allows the electric dipole effects of several Hilbert curves to be combined in order to improve the electric dipole behavior of the metal track, and thus improve the homogenization effect of the RF field by the metal track.

In particular, the use of 3^{rd} order Hilbert curves allows a metal track to be obtained with an unwound length that is between approximately 0.5 times and approximately 1.5 times a wavelength of a radio frequency field used in an ultra-high-field MRI device, for example, a wavelength of 100 cm to 7 T (or from 240 cm to 3 T) and which, once folded, occupies a two-dimensional surface that is large enough to cover a part of a body to be imaged, such as, for example, a head or members of the pelvic area.

According to one or more embodiment(s), the metal tracks can be arranged in a pattern that includes 4^{th} order Hilbert curves or other orders, or combinations of Hilbert curves with different orders. In these configurations, the metal tracks thus formed maintain a symmetry that is compatible with an interaction with the antenna as an electric dipole. In particular, the metal tracks thus formed include a plane of symmetry that is normal to the electrical component of the RF field emitted by the antenna.

According to one or more embodiment(s), the device further includes a dielectric substrate, with said first metal track being arranged on said dielectric substrate.

This allows the mechanical structure of the metal track to be maintained.

According to one or more embodiment(s), the thickness of said substrate ranges between approximately 10 micrometers and approximately 1 mm. This facilitates the placement of the device between the volumetric antenna and the part of the body to be imaged. This is particularly advantageous within the context of use in a 7 T MRI device, when limited space is available between the volumetric antenna and the part of the body.

A low substrate thickness advantageously also allows it to be provided with a flexible nature, facilitating the adaptation of the shape of the device to the geometry of a part of the body in order to place the device as close as possible to said part of the body, which improves the amplitude of the radio frequency field reaching said part of the body.

According to one or more embodiment(s), said substrate includes a dielectric loss factor at the frequency of the radio frequency field, preferably less than a value of approximately 0.05. This allows the efficiency of the device to be optimized by limiting the absorption of the radio frequency field by said substrate.

In the present description, the dielectric loss factor (or loss angle) is a dimensionless quantity as understood by a person skilled in the art in the microwave field. For a dielectric material, it is approximately equal to the ratio between the imaginary part and the actual part of the complex dielectric constant of the material. The dielectric loss factor particularly depends on the frequency of the considered radio frequency field.

According to one or more embodiment(s), the device further comprises a second metal track identical to said first metal track, separate from said first metal track, with said first metal track and said second metal track occupying an overall surface with a largest dimension ranging between approximately 5% and approximately 15% of said wavelength of the radio frequency field.

The overall area occupied by said first metal track and said second metal track is greater than the surface occupied by only one of said metal tracks.

In other words, a larger dimension for the surface occupied by said first metal track and said second metal track is identical to a larger dimension of the surface occupied by a single metal track.

This allows, with said metal tracks, a larger surface to be occupied than with a single metal track, yet without changing the length and the electrical dipole properties of each metal track. For example, two separate metal tracks can be used, each made up of two connected 3^{rd} order Hilbert curves. Despite the resemblance with a track based on a single 4^{th} order Hilbert curve, the use of two tracks according to the invention is advantageous since it allows an electric dipole behavior to be maintained for the assembly formed by the two metal tracks, which provides better homogenization of the RF field and is compatible with use in a birdcage type volumetric antenna.

According to one or more embodiment(s), the homogenizing device particularly can be arranged in the volumetric antenna and in contact with said part of the body to be imaged. According to one or more embodiment(s), said volumetric antenna is a birdcage type antenna configured to be placed around a brain or an area of a brain; the frequency corresponding to said wavelength of the radio frequency field is approximately 300 MHz. The metal track then occupies, for example, a rectangular shaped surface including sides with lengths ranging between approximately 5 cm and approximately 15 cm.

According to one or more embodiment(s), the system for emitting a radio frequency field for magnetic resonance imaging further comprises a second homogenizing device, with the two devices being placed on either side of the part of the body to be imaged. The second homogenizing device comprises, according to one or more example(s), all or some of the features of the first homogenizing device.

According to a second aspect, the present description relates to a method for emitting a radio frequency field for a magnetic resonance imaging device comprising:
emitting, by a volumetric antenna of the system according to the first aspect, a radio frequency field comprising a spectrum centered on a given wavelength; and
homogenizing said radiofrequency field by means of a device for homogenizing the system according to the first aspect arranged between the volumetric antenna and said part of the body to be imaged.

According to one or more embodiment(s), the homogenizing device is arranged in the volumetric antenna and in contact with a part of a body to be imaged.

According to one or more embodiment(s), the homogenization of said radiofrequency field is carried out by the additional arrangement of a second homogenizing device, with the two devices being placed on either side of the part of the body to be imaged.

This increases the homogeneity of the distribution of the radio frequency field in two different areas of a part of a body to be imaged, for example, the temporal lobes of a brain or two areas of the abdomen.

### BRIEF DESCRIPTION OF THE DRAWINGS

Further advantages and features of the invention will become apparent upon reading the description, which is illustrated by the following figures:

FIG. 1A shows a first example of a device according to the present description;

FIG. 1B shows a second example of a device according to the present description;

FIG. 2 shows examples of Hilbert curves with different orders used in devices according to the present description;

FIG. 3 shows simulation results showing the distribution of the excitation radio frequency field with an example of a device according to the present description;

FIG. 4 shows experimental results showing the distribution of the excitation radio frequency field with an example of a device implementing a unilateral configuration, according to the present description;

FIG. 5 shows experimental results showing the distribution of the excitation radio frequency field with an example of a device implementing a bilateral configuration, according to the present description;

FIG. 6 shows experimental results showing the distribution of the RF signal with an example of a device implementing a unilateral configuration, according to the present description;

FIG. 7 shows experimental results showing the distribution of the RF signal with an example of a device implementing a bilateral configuration, according to the present description;

FIG. 8 shows an example of a system for emitting a radio frequency field according to the present description.

### DETAILED DESCRIPTION OF THE INVENTION

In the figures, some elements are not shown to scale for better visibility.

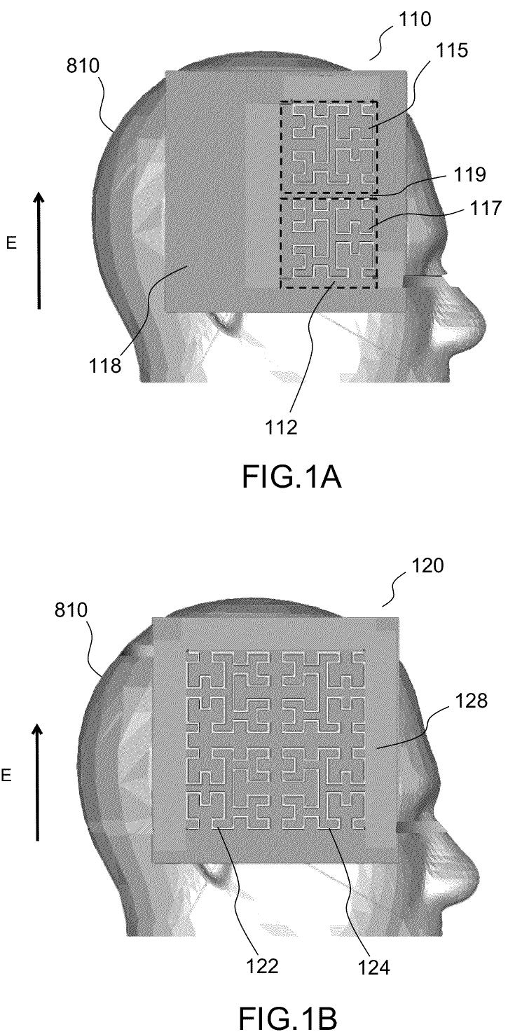

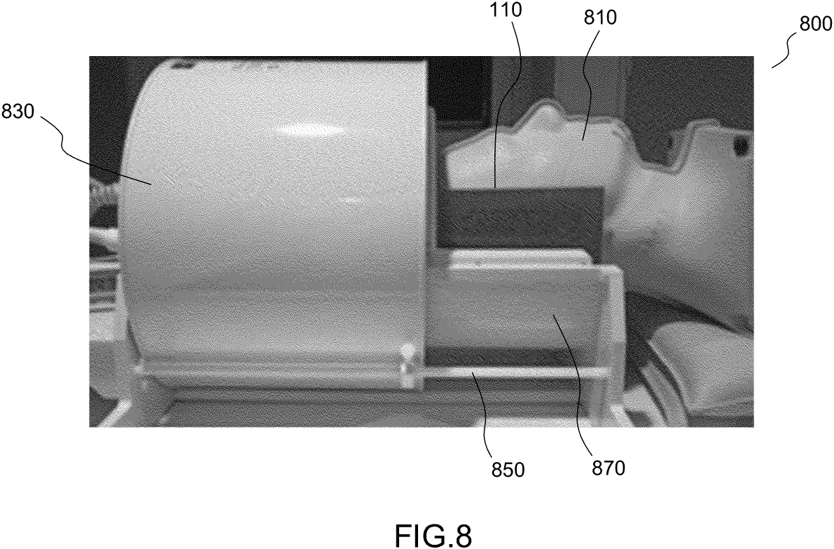

FIGS. 1A and 1B illustrate examples of devices 110, 120 according to the present description and FIG. 8 illustrates an example of a system 800 for emitting a radio frequency (RF) field for a magnetic resonance imaging (MRI) device according to the present description, in which a device according to the present description can be used, for example, a device as illustrated in FIGS. 1A, 1B. In FIGS. 1A, 1B, a head 810 is schematically shown in order to show the positioning and the order of quantities of the dimensions of the device relative to the parts of the body.

In general, as illustrated in FIG. 8, emission systems 800 according to the present description include a volumetric antenna 830 for emitting an RF field and one or more device(s) 110 for homogenizing the RF field. Such systems 800 are configured to fit around a part 810 of a body to be imaged and to emit, in this part of the body, a homogeneous RF field at a given frequency in order to excite atomic nuclei therein.

The part of the body to be imaged optionally can be disposed on a support 870, around which the volumetric antenna 830 is positioned. The positioning can be implemented by sliding the volumetric antenna 830 along a positioning slide 850.

The frequency, called Larmor frequency, of the RF field used to excite the atomic nuclei of the part of the body to be imaged depends on the type of atomic nuclei to be excited and on the main magnetic field of the MRI device.

The Larmor frequency can be, for example, approximately 300 MHz in the case of nuclei of hydrogen atoms in a main magnetic field of approximately 7 T. The wavelength of the RF field that is used therefore can be, for example, approximately 1 m.

FIG. 1A illustrates a first example of a device 110 for homogenizing a radio frequency field according to the present description, also called “homogenization pads” of the RF field. In this example, the device 110 comprises a metal track 112 arranged on a substrate 118. As will be described in further detail hereafter, the metal track 112 is arranged in a pattern comprising a first curve 115 and a second curve 117 connected together at a connection point 119.

The metal track 112 is continuous, with a length ranging between approximately 0.5 times and approximately 1.5 times the wavelength of the RF field used by the MRI device. In practice, the metal track 112 is intended to occupy a sufficient surface in order to cover the part 810 of the body to be imaged.

Thus, according to the embodiments, the largest dimension of the surface occupied by the metal track ranges between approximately 5% and 15% of the wavelength of the RF field. This dimension particularly allows the surface to be able to cover the part of the body to be imaged, such as, for example, an area of the brain or a pelvic area.

In particular, in the cases whereby the device is applied to MRI of the brain, said dimensions ensure the effectiveness of the device on the lateral or temporal lobes, which are areas in which the RF field is generally hardly present when a birdcage antenna is used without a homogenization pad.

In some cases, an area larger than the surface covered by a single metal track may need to be imaged.

FIG. 1B thus illustrates a second example of a device 120 for homogenizing a radio frequency field according to the present description. In this example, the device 120 comprises two metal tracks 122, 124 arranged on a substrate 128. In this example, the metal tracks 122, 124 are identical. More specifically in this example, each of the two metal tracks 122, 124 of the dual-structure device 120 has a geometry identical to the metal track 112 of the single-structure device 110.

In this example, the two metal tracks 122, 124 occupy an overall surface of approximately 5% to approximately 15% of the wavelength of the RF field and with a width of approximately 5% to approximately 15% of the wavelength of the RF field. Thus, in this example, the overall surface occupied by the metal tracks assumes a square shape, while the surface occupied by a single metal track assumes a rectangular shape. The square shape of the total surface occupied by the tracks 122, 124 is advantageous in that it allows an MRI image to be acquired of a larger part of the body than can be acquired with a single metal track 112. In FIGS. 1A and 1B, the orientation of the electrical component (E) of the RF field emitted by a volumetric antenna with which the device is used is shown by an arrow. According to the embodiments shown in FIGS. 1A and 1B, each of the metal tracks 112 or 122, 124 is arranged in a pattern having symmetry providing the device with electrical dipole properties that can interact with a volumetric antenna. Specifically, it can be seen that the metal track 112 has a horizontal axis of symmetry (that is, from left-to-right in FIG. 1A) passing through the connection point 119 and that there is a plane of symmetry passing through this axis that is normal to the axis of the electrical component (E) of the RF field emitted by a volumetric antenna of an MRI device in which the device is used (with this axis in this case being directed vertically from the bottom to the top in FIG. 1A, as indicated by the arrow). As a result of said symmetry, it also can be seen that, in the configurations shown in FIGS. 1A-1B, the straight line connecting the two ends of the track 112 (or 122 or 124) is parallel to the electrical component (E) of the RF field emitted by the volumetric antenna.

According to the embodiments, the substrate 118, 128 on which the metal track 112 or the metal tracks 122, 124 are respectively printed is a material used for manufacturing a printed circuit such as FR-4 (abbreviation for Flame Resistant 4).

The dimensions of the substrate 118, 128 are sufficient to contain one to two metal tracks depending on the single or dual structure of the device 110, 120 that is used.

The thickness of the substrate 118, 128 is thin enough to allow the device to be easily placed between the volumetric antenna 830 and the part of the body 810 to be imaged. This thickness can range between approximately 10 microns and approximately 1 mm.

The substrate includes a dielectric material with a low dielectric loss factor, preferably less than approximately 0.05. It is the value of the dielectric loss factor assessed at the frequency of the RF field that is used.

According to the present description, embodiments of the device are intended to be used in brain imaging. The devices are therefore intended to be placed between an antenna or the walls of an antenna, for example, of the birdcage type, and a head to be imaged.

A low thickness of the homogenizing devices advantageously allows the antennas 830 (FIG. 8) to be placed as close as possible to the head to be imaged, for example, within approximately one mm or approximately a few mm, in order to improve the contrast of the MRI image. This can also provide the device with a flexible nature that allows the device to conform to the geometry of a part of the body to be imaged.

The applicant has shown that the metal track of a homogenizing device according to the present description can be arranged in a pattern comprising a Hilbert curve.

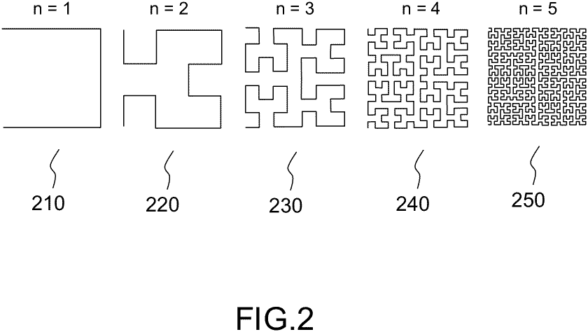

FIG. 2 thus shows examples of Hilbert curves with different orders that can be used in devices according to the present description.

More specifically, FIG. 2 shows an illustration of curves 210, 220, 230, 240, 250 with a Hilbert fractal geometry (or Hilbert curves) with different orders n, depending on their mathematical definition.

For a given overall track length, Hilbert curves with different orders can be used. In particular, the higher the order of the Hilbert curves that are used, the more the track is folded and the smaller the dimensions of the two-dimensional space occupied by the track.

Within the context of the invention, the use of a geometry of the Hilbert curve type in practice allows folding of a metal track with a given overall length in order to reduce the two-dimensional space that it occupies on a surface, while maintaining the same overall length (unwound length). This particularly allows a metal track according to an embodiment of the invention to be able to interact with volumetric antennas emitting RF fields with a wavelength greater than the dimensions of the surface occupied by the metal track.

Thus, in the example of the device 110 shown in FIG. 1A, each of the two Hilbert curves 115, 117 is a 3^{rd} order Hilbert curve, therefore similar to the curve 230 shown in FIG. 2. According to the example of FIG. 1A, the device is a single-structure pad 110 comprising a single metal track 112 arranged in a pattern comprising two 3^{rd} order Hilbert curves connected to the connection point 119.

As can be seen in FIG. 1B, the metal tracks 122, 124 form an assembly structurally different from a Hilbert curve of the order n = 4, like the curve 240 (FIG. 2), since the two metal tracks 122, 124 are separate. However, according to the embodiments of the invention, the metal tracks can be arranged in a pattern that includes 4^{th} order Hilbert curves or other orders of Hilbert curves, or combinations of Hilbert curves with different orders.

According to one or more embodiment(s), said first metal track is configured to form an electric dipole comprising a natural frequency strictly higher than a Larmor frequency used by an MRI device (for example, 300 MHz for an ultra-high-field MRI device at 7 T or 125 MHz for a high-field MRI device at 3 T).

This allows the metal track to have a natural frequency strictly higher than the frequency of the RF field used in an MRI device. In this way, the device can interact with the RF field in order to homogenize it without being resonant with this field.

In particular, the applicants have observed that the presence of the human body near the electric dipole formed by the metal track of the device according to the present description tends to decrease the natural frequency of the electric dipole. It is therefore advantageous to configure the metal track so that the electric dipole has a natural frequency that is initially higher than the frequency of the RF field used in order to prevent the presence of the human body from rendering said natural frequency lower than said frequency of the RF field when the device is used.

In the case whereby the device comprises two metal tracks 122, 124, each of said two metal tracks 122, 124 is configured to form an electric dipole comprising a natural frequency strictly higher than a Larmor frequency used by an MRI device (for example, 300 MHz for an ultra-high-field MRI device at 7 T or 125 MHz for a high-field MRI device at 3 T).

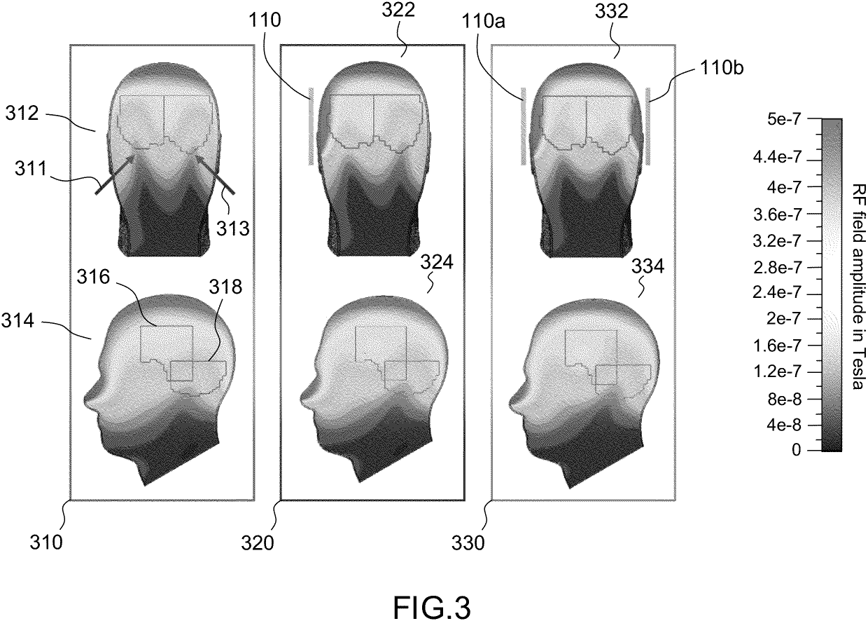

FIG. 3 shows simulation results showing the distribution of the excitation RF field with an example of a device according to the present description.

In particular, the simulations model the distribution of a 300 MHz frequency RF field (corresponding to that used in ultra-high field MRI devices at 7 T) when used for imaging a brain.

The simulations use the parameters of a birdcage type antenna made up of 16 metal bars, for an overall diameter of approximately 26 cm and an overall height of approximately 24 cm. The head model used is a SAM (Specific Anthropomorphic Mannequin) phantom model conventionally used in this type of simulation. The SAM model is a mannequin that has standardized properties close to those of the human body (dielectric permittivity: εᵣ= 42, electrical conductivity: 0.99 S/m and density 1,000 kg/m³).

The simulations are carried out with the CST Microwave Studio® simulation software in order to assess the distribution of the RF magnetic field as well as the specific absorption rate (SAR).

The SAR (expressed a W/kg) quantifies the amount of electromagnetic power absorbed by the tissues of the human body, which is subsequently dissipated in the form of heat. This quantity is typically used by a person skilled in the art to assess safety criteria for the use of radiation devices for a patient.

FIG. 3 particularly shows simulations of the distribution of the RF field in a brain in three cases: without a homogenization pad (reference configuration 310); with a single homogenization pad, in this example a pad 110 as illustrated in FIG. 1A, placed on only one side of the brain (unilateral configuration 320); and with two homogenization pads 110a, 110b, in this configuration two pads 110 as illustrated in FIG. 1A, placed on each side of the brain (bilateral configuration 330).

The pads used in the simulations in particular are pads with a metal track occupying a surface with a length of 10.4 cm and a width of 4.8 cm.

For each of the three configurations, the median coronal plane is shown at the top (312, 322, 332) and the median sagittal plane is shown at the bottom (314, 324, 334). The areas delimited by a black line (for example, the areas of interest 316 and 318) indicate areas of interest corresponding to different regions of the brain. The areas shown by the arrows 311, 313 indicate an example of shadow areas in which the RF field is very low due to a lack of homogeneity of the RF field. According to one or more embodiment(s), the device of the invention aims to eliminate these shadow areas by homogenizing the distribution of the RF field throughout the entire part of the body to be imaged.

FIG. 3 shows that adding a homogenization pad according to the present description allows the shadow areas in the brain to be eliminated by reintroducing the signal by homogenizing the excitation RF field.

Moreover, the homogeneity of the RF field in the area of the cerebellum is not overly affected by the presence of the pads. This aspect is noteworthy in that it differs from the pads known from the prior art, which are based on dielectric materials.

TABLE 1

| | Reference | Unilateral MTMF | Bilateral MTMF |
|---|---|---|---|
| Left-hand temporal area | 0.242 ± 0.074 | 0.249 ± 0.075 | 0.280 ± 0.073 |
| Right-hand temporal area | 0.263 ± 0.076 | 0.282 ± 0.071 | 0.270 ± 0.071 |
| Rear area | 0.195 ± 0.071 | 0.187 ± 0.073 | 0.177 ± 0.072 |

The results of the statistical averages of the values of the RF field in different areas of the brain for different configurations of the device are consolidated in Table 1 above. They show a clear improvement in the mean value of the amplitude of the RF field in the temporal areas (+16% for the unilateral configuration and +10% for the bilateral configuration), as well as a reduction of the standard deviation of the amplitudes of the RF field. The reduction of the standard deviation in the rear area is -10%, which is acceptable compared to the other solutions known from the prior art, for example, the dielectric pads disclosed in the published patent application EP 3550321.

The CST Microwave Studio® simulation software also allows an absorbed power budget to be implemented in the brain of the phantom model. The quantity of interest is the specific absorption rate (SAR) for which the averaged value can be taken over an entire volume of a part of the body (overall value) or the maximum value in volumes equivalent to 10 g of tissue (local value).

Table 2 below consolidates the SAR results simulated for different configurations of the device according to the embodiments of the invention. The results of table 2 show a 60% increase of the local SAR in the case of the bilateral configuration. This effect can be counterbalanced by a slight increase in the distance between the device and the head, typically less than or equal to approximately 1 cm. This is a compromise between increasing the signal in the shadow areas and the local SAR.

Table 2 below shows that the local SAR for imaging the brain remains low, even with the proximity of the antenna and the imaged areas.

TABLE 2

| | Reference | Unilateral MTMF | Bilateral MTMF |
|---|---|---|---|
| Overall SAR W/kg | 0.101 | 0.103 | 0.105 |
| Local SAR (10 g) W/kg | 0.452 | 0.740 | 0.731 |

Experimental tests showing the effect of the device on the distribution of an RF field with a frequency of 300 MHz in the context of MRI of the brain have also been carried out by the applicants in order to confirm the homogenization function of the device according to the present description.

In these experimental tests, the antenna used is a “1T/32R” model birdcage antenna marketed by Nova Medical®, that is, a quadrature antenna with 1 transmission channel and a reception network comprising 32 loops that is adapted to imaging the brain by an ultra-high-field MRI device at 7 T.

The model used for the brain is a head of an anthropomorphic dummy (SAM/Speag^{®} model) with electromagnetic properties close to the human body (dielectric permittivity: εᵣ = 45.3, electrical conductivity: 0.87 S/m).

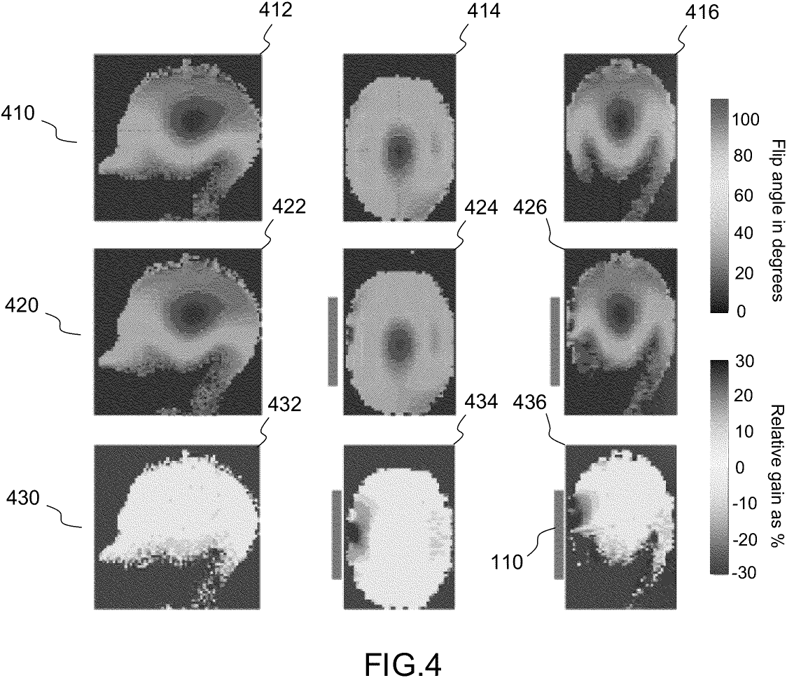

FIG. 4 shows experimental results showing the distribution of the excitation RF field with an example of a device implementing a unilateral configuration, according to the present description.

In particular, FIG. 4 shows results of measuring the flip angle (quantity proportional to the amplitude of the RF field) in the brain phantom model described above for different measurement configurations: without a homogenization pad (reference configuration 410), with a homogenization pad according to the present description in a unilateral configuration 420, as well as a comparison 430 between these two configurations representing the relative signal gain between the two configurations.

For each measurement configuration, the results are presented in a sagittal section (412, 422, 432), an axial section (414, 424, 434), and a coronal section (416, 426, 436).

The pad used herein is a dual-structure device, as illustrated, for example, in FIG. 1B, placed on one side of the brain.

The results show a very positive effect of the device on the amplitude of the RF field (+10% to +30% increase of the flip angle) on the right-hand temporal area of the brain (this is visible on sections 434, 436). It also can be seen on the sagittal section (432) that the device does not introduce RF field losses at the rear of the brain.

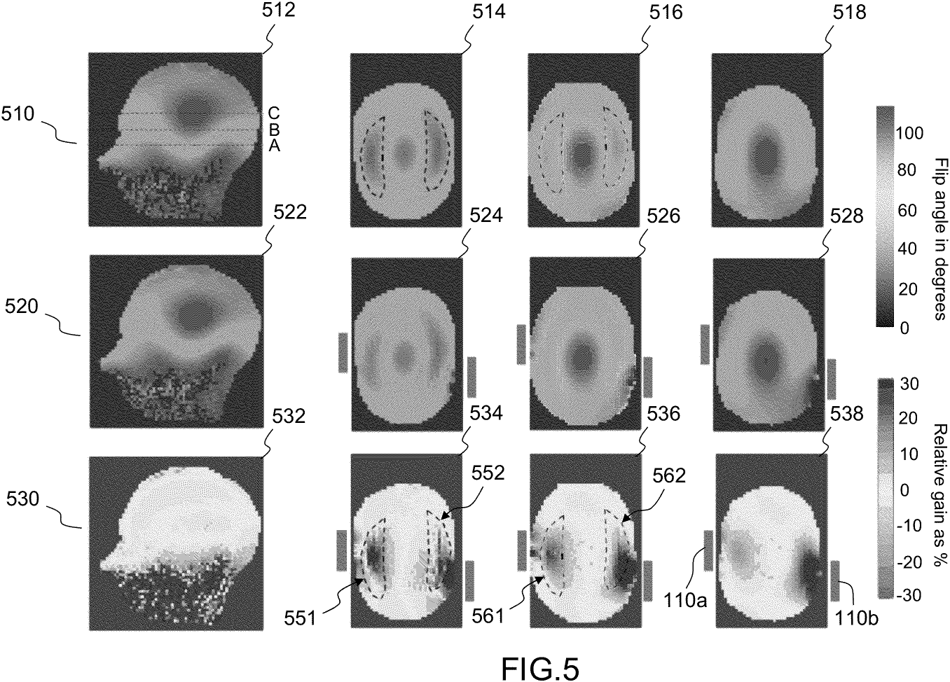

FIG. 5 shows experimental results showing the distribution of the excitation RF field with an example of a device implementing a bilateral configuration, according to the present description.

In particular, FIG. 5 shows results of measuring the flip angle in the brain phantom model described above for different measurement configurations: without a homogenization pad 510, with homogenization pads in a bilateral configuration 520 according to the present description, as well as a comparison 530 between these two configurations.

In this case, the pads used are a set of two single-structure devices 110a, 110b according to the present description, placed on either side of the brain. The positions of the pads relative to the head are schematically shown by two black rectangles 590, 591.

For each measurement configuration, the results are presented in a sagittal section 512, 522, 532, and three axial sections (section A: 514, 524, 534; section B: 516, 526, 536 and section C: 518, 528, 538) corresponding to planes (A, B and C) indicated by dashed lines in the sagittal view 512 on the top left-hand side.

The results shown in FIG. 5 show a very positive effect (+10% to +30% increase of the flip angle) on the two temporal areas of the brain (551, 552, 561, 562). The sagittal section 532 of FIG. 5 particularly shows that the device introduces an improvement in the homogeneity of the RF field by reintroducing the RF field at the rear of the brain.

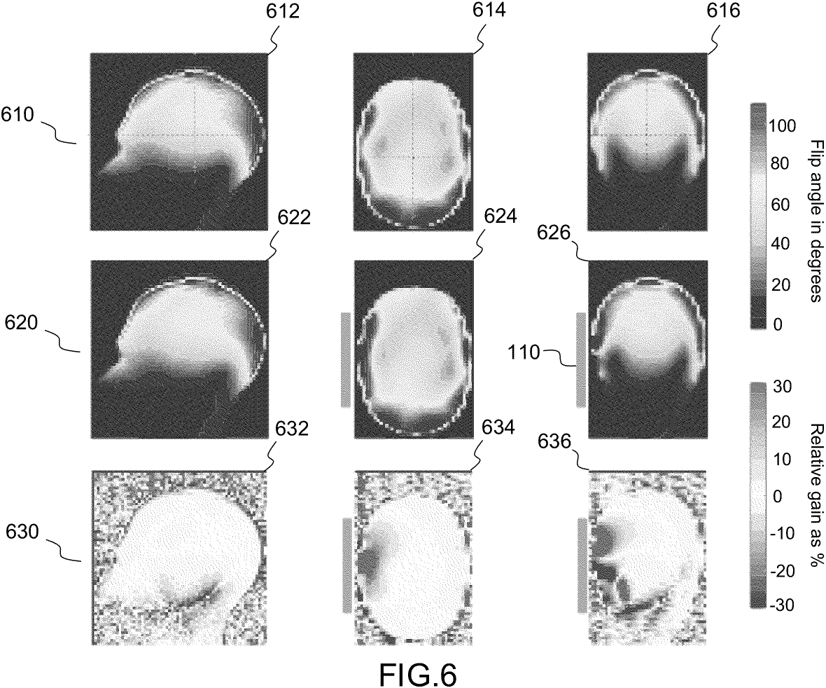

FIG. 6 shows experimental results showing the distribution of the RF signal with an example of a device implementing a unilateral configuration, according to the present description.

In particular, FIG. 6 shows results of measuring the flip angle during a gradient echo sequence in the brain phantom model described above for different measurement configurations: without a homogenization pad (reference configuration 610), with a homogenization pad of the same type as the pad 110 shown in FIG. 1A (unilateral configuration 620), as well as a comparison between these two configurations 630. The gradient echo is a sequence of RF field pulses and of main magnetic field gradients commonly used in MRI, the device according to the present description is nevertheless not limited to a use within the context of a particular sequence.

The results of FIG. 6 show that the device of the invention does not disrupt the reception of the RF signal by the reception channels of the birdcage antenna in the case of a gradient echo sequence.

For each measurement configuration, the results are presented in a sagittal section 612, 622, 632, an axial section 614, 624, 634, and a coronal section 616, 626, 636.

FIG. 6 shows that the presence of a device improves the RF signal obtained during the standard sequence. In particular, it can be seen that the comparisons 630 shown in FIG. 6 are close to the comparisons 430 shown in FIG. 4, which confirms that the presence of an example of a dual-structure device 120 according to the present description, placed on one side of the brain, does not disrupt the reception of the RF signal by the reception channels of the birdcage antenna.

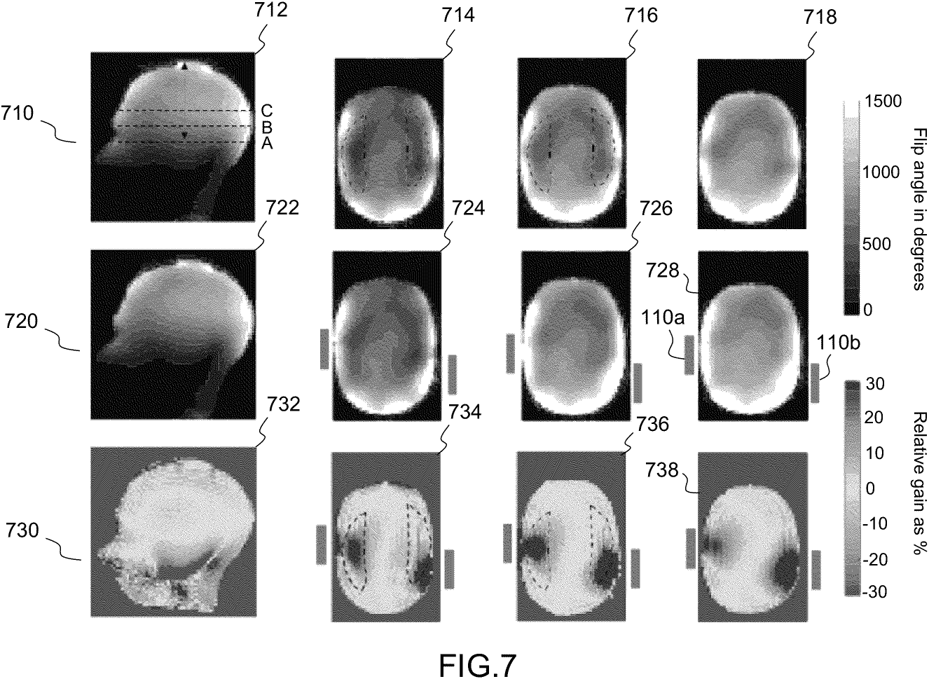

In the same way, FIG. 7 shows results of measuring the flip angle during a gradient echo sequence in a brain phantom model for different measurement configurations: without a homogenization pad (reference configuration 710), with two homogenization pads 110a, 110b (bilateral configuration 720), as well as a comparison 730 between these two configurations. In this example, each pad 110a, 110b is a pad of the type illustrated in FIG. 1A.

For each measurement configuration, the results are presented in a sagittal section 712, 722, 732, and three axial sections (section A: 714, 724, 734; section B: 716, 726, 736 and section C: 718, 728, 738) corresponding to planes (A, B and C) indicated by dashed lines in the sagittal view 712 on the top left-hand side.

FIG. 7 confirms that the presence of the two pads placed on either side of the brain does not disrupt the reception of the RF signal by the reception channels of the birdcage antenna. Although described by means of a number of embodiments, the devices for homogenizing an RF field of an MRI device according to the present description include various alternative embodiments, modifications, and improvements that will become clearly apparent to a person skilled in the art, with it being understood that these various alternative embodiments, modifications and improvements form part of the scope of the invention as defined by the following claims.

1. A system for emitting a radio frequency field for a magnetic resonance imaging device, said radio frequency field comprising a spectrum centered on a given wavelength, said system comprising:
a volumetric antennaconfigured to emit said radio frequency field, said volumetric antennabeing configured to be placed around a partof a body to be imaged; and
a devicefor homogenizing the radio frequency field, configured to be arranged between said volumetric antenna and said part of the body to be imaged;
wherein the homogenizing device comprises:
at least one first continuous metal trackwith an overall length of approximately 0.5 to approximately 1.5 times said wavelength of the radio frequency field; wherein:
said first metal trackoccupies a surface with a largest dimension ranging between approximately 5% and approximately 15% of said wavelength of the radio frequency field;
wherein said first metal trackis arranged in a pattern comprising a plane of symmetry that is normal to the electrical component of the radio frequency field emitted by the volumetric antenna, so as to provide the homogenizing device with an electric dipole property comprising a natural frequency strictly higher than the frequency corresponding to said wavelength of the radio frequency field.

2. The system as claimed in claim 1, wherein said first metal track is arranged in a pattern comprising a first 3^{rd} order Hilbert curveand a second 3^{rd} order Hilbert curveconnected to each other.

3. The system as claimed in claim 1 wherein said first metal trackoccupies a surface with a largest dimension ranging between approximately 5 cm and approximately 15 cm.

4. The system as claimed in claim 1 further comprising a dielectric substrate, with said first metal trackbeing arranged on said dielectric substrate.

5. The system as claimed in claim 4, wherein the thickness of said substrateranges between approximately 10 micrometers and approximately 1 mm.

6. The system as claimed in claim 4, wherein said substrateincludes a dielectric loss factor, assessed at the frequency corresponding to said wavelength of the radio frequency field, of less than approximately 0.05.

7. The system as claimed in claim 1, further comprising a second metal trackidentical to said first metal track, separate from said first metal track, with said first metal trackand said second metal trackoccupying an overall surface with a largest dimension ranging between approximately 5% and approximately 15% of said wavelength of the radio frequency field.

8. The system as claimed in claim 1, wherein said volumetric antenna is a birdcage type antenna configured to be placed around a brain or an area of a brain.

9. The system as claimed in claim 1, further comprising a second homogenizing device, with the two devicesbeing placed on either side of the part of the body to be imaged.

10. A method for emitting a radio frequency field for magnetic resonance imaging of a part of the body comprising:
emitting, by a volumetric antennaof the system as claimed in claim 1, a radio frequency field comprising a spectrum centered on a given wavelength; and
homogenizing said radio frequency field by means of a devicefor homogenizing the system as claimed in claim 1 arranged between the volumetric antennaand the part of the body to be imaged.

11. The method for emitting a radio frequency field for magnetic resonance imaging as claimed in claim 10, wherein the homogenization of said radio frequency field is carried out by the additional arrangement of a second homogenizing device, with the two devicebeing placed on either side of the part of the body to be imaged.
